(19) United States
(12) Patent Application Publication
(10) Pub. No.: US 2024/0042863 A1
(43) Pub. Date: Feb. 8, 2024

(54) Method and Equipment for Monitoring a Failure in a High-Voltage Circuit of a Vehicle, and High-Voltage Circuit System

(71) Applicant: Bayerische Motoren Werke Aktiengesellschaft, Muenchen (DE)

(72) Inventors: Christian ALLGAEUER, Muenchen (DE); Martin BEER, Muenchen (DE); Michael BRANDMAYER, Hoerlkofen (DE); Marcel EWERS, Dachau (DE); Matthias HAMMER, Muenchen (DE); Sebastian HERRMANN, Beijing (CN); Alexander KOWALLIK, Schaeftlarn (DE); David MAIER, Muenchen (DE); Aikaterini PAPATHANASIOU, Muenchen (DE); Ludwig SCHIRMACHER, Oxford (GB); Manuel SCHWARZ, Ingolstadt (DE)

(21) Appl. No.: 18/268,999

(22) PCT Filed: Dec. 21, 2021
(86) PCT No.: PCT/EP2021/087095

§ 371 Date: Jun. 22, 2023

(30) Foreign Application Priority Data
Dec. 22, 2020 (CN) 202011555054.6

(51) Int. Cl. B60L 3/00; B60L 50/60; G01R 31/00; G01R 31/28

(52) U.S. Cl. CPC B60L 3/0046; B60L 50/60; G01R 31/007; G01R 31/2843; G01R 31/2834; B60L 2240/547

(57) ABSTRACT

A method for monitoring a failure in a high-voltage circuit of a vehicle includes obtaining a supply voltage of a high-voltage power supply device; obtaining component voltage(s) on one or more high-voltage components powered by the high-voltage power supply device; comparing the supply voltage with each component voltage; and determining that a failure exists in the high-voltage circuit when the voltage difference between the supply voltage and any one of the component voltage(s) exceeds a predetermined threshold. Also disclosed are a computer readable storage medium, an equipment for monitoring a failure in a high-voltage circuit of a vehicle, a high-voltage circuit system for a vehicle, and a vehicle comprising the high-voltage circuit system.

### TECHNICAL FIELD

The present application relates to a method for monitoring a failure in a high-voltage circuit of a vehicle, a computer-readable storage medium, an equipment for monitoring a failure in a high-voltage circuit of a vehicle, a high-voltage circuit system for a vehicle and a vehicle.

### BACKGROUND

In a conventional electric vehicle, in order to recognize the fault in a high-voltage circuit, a high-voltage interlock loop or HVIL-Hazardous Voltage Interlock Loop is used, wherein a low-voltage detection line on which a low-voltage signal is applied is used for detecting the integrity of the whole high-voltage circuit. The low-voltage detection line is usually arranged parallel to the high-voltage line. At each high-voltage component, in particular at the connector of each high-voltage component, it is short-circuited by an associated monitor. The low-voltage detection lines at all the high-voltage components are connected in series and form a complete circuit. Once the low-voltage signal is interrupted, it means the high-voltage circuit has a fault and the high-voltage supply can be cut off based on this, so that the vehicle is in a safe state.

However, in order to construct such a high voltage interlock loop, it is necessary to provide an additional low-voltage power supply, cables of the low-voltage detection line, the monitor assigned to each of the high-voltage components and the detection means for the low-voltage signal. On one hand, this increases the complexity of the circuit and may also introduce the additional failure causes, and on the other hand, this also brings additional hardware costs and assembling and wiring costs in the vehicle manufacturing.

Besides, such a high-voltage interlock loop is a series circuit. When the high-voltage interlock loop is interrupted, it is not possible to know the signal interruption or the location of the fault or the high-voltage component involved in the fault.

### SUMMARY

The object of the present disclosure is to realize the monitoring of a failure in a high-voltage circuit of a vehicle without additional hardware costs, so as to ensure the safety of the vehicle without increasing the complexity of the circuit.

The aforesaid object of the present disclosure is achieved by a method for monitoring a failure in a high-voltage circuit of a vehicle according to the present disclosure, a computer-readable storage medium, an equipment for monitoring a failure in a high-voltage circuit of a vehicle, a high-voltage circuit system for a vehicle and a vehicle according to the present disclosure.

According to the first aspect of the present disclosure, the method for monitoring a failure in a high-voltage circuit of a vehicle, the method comprising:
obtaining a supply voltage of a high-voltage power supply device;
obtaining component voltage(s) on one or more high-voltage components powered by the high-voltage power supply device;
comparing the supply voltage with each component voltage;
determining that a failure exists in the high-voltage circuit when the voltage difference between the supply voltage and any one of the component voltage(s) exceeds a predetermined threshold.

It should be noted first, in the range of the present disclosure, the vehicle is defined as vehicle having a high-voltage power supply device and high-voltage components. Here, said vehicle may particularly involve electric vehicle (EV), such as fuel cell vehicle (FCV) and pure electric vehicle (BEV) as well as hybrid electric vehicle (HEV), such as plug-in hybrid electric vehicle (PHEV), extended range electric vehicles (EREV), etc. It is also possible that the vehicle is other type of vehicle having a high-voltage power supply device and high-voltage components.

In the present disclosure, in order to monitor a failure in a high-voltage circuit of a vehicle, firstly obtaining a supply voltage of a high-voltage power supply device and component voltage(s) on one or more high-voltage components powered by the high-voltage power supply device. Here, since the high-voltage components are connected in parallel to the high-voltage power supply device, in the ideal situation, each of the high-voltage components should obtain the same high-voltage power supply. Therefore, the supply voltage can be used as reference to compare with each component voltage. When the voltage difference between the supply voltage and any one of the component voltage(s) exceeds a predetermined threshold, under the consideration of the voltage sensor accuracy and the current fluctuation or other factors, it can be determined advantageously that the obtained component voltage of the high-voltage component is not identical with the power supply voltage, thereby determining simply and conveniently a failure existing in the high-voltage circuit. Here, for example, the threshold value can be predetermined as exact voltage value, such as 10V, 20V or more. It may be also considered to predetermine the threshold value as a certain proportion of the power supply voltage, such as 5% or 10% of the supply voltage.

In the high-voltage power supply device and in the high-voltage components, in order to ensure their operation, they are generally provided with their own control unit and voltage sensor. The present disclosure advantageously utilizes the existing components of the high-voltage power supply device and the high-voltage components to monitor the high-voltage circuit composed of the high-voltage power supply device and the high-voltage components. With respect to the conventional high-voltage interlock loop, the means and corresponding parts required by the whole low-voltage detection circuit can be omitted. It can be said, the monitoring according to the present disclosure almost no longer needs to provide additional hardware, thereby reducing the vehicle manufacturing cost and assembly cost. Meanwhile, it can detect the integrity of the high-voltage circuit of a vehicle in the simple manner without increasing the complexity of the circuit, so as to ensure the safety of the vehicle.

Besides, since the failure monitoring of the present disclosure is based on the comparison result of the supply voltage of the high-voltage power supply device with each component voltage, it is also easy to know which one of the high-voltage components involves the fault, thereby making the subsequent detection and maintenance convenient. This will bring the technical advantage which cannot be achieved by the high-voltage interlock loop.

In accordance with an embodiment of the present disclosure, the failure includes: loosening of the plug connection of the high voltage cable at the high voltage power supply device, loosening of the plug connection of the high voltage cable at the high voltage component(s), interruption of the high voltage cable, short circuit of the high voltage component and open circuit of the high voltage component. Here, since the loose or poor plug connection, even disconnection of the high-voltage cable on each component will render the voltage on two sides of the connection inconsistent, it is advantageous to detect the situation of plug connection through comparing the voltages. Although anode and cathode of a plug of a high-voltage cable are usually distinguishable through the structure of the plug, yet the misconnection or wrong connection of a plug connection also can be detected through comparing the voltages. Besides, the interruption of the high-voltage cable itself and the abnormality occurring to the high-voltage component, such as short-circuit or open-circuit, also can be detected by the failure monitoring according to the present disclosure. Therefore, an effective monitoring for various failure in the high-voltage circuit can be realized according to the present disclosure.

According to an embodiment of the present disclosure, the supply voltage is: battery voltage of the high-voltage battery in the high-voltage power supply device, intermediate circuit voltage of the intermediate circuit in the high-voltage power supply device, or external voltage provided to the vehicle by the power supply external to the vehicle. In the present disclosure, with respect to the use of a fixed rated supply voltage, using the battery voltage of the high-voltage power supply device as supply voltage to compare with the component voltage of the high-voltage component can advantageously eliminate the influence due to the constant change of the state of charge (SOC) and the state of health (SOH) of the high-voltage battery during use. Besides, the high-voltage power supply device may further be provided with an intermediate circuit, in particular an intermediate circuit capacitor, for stably outputting voltage. Here, the intermediate circuit voltage also can be used as reference. It is also possible that the vehicle uses the power supply external to the vehicle as high-voltage power supply device for charging the battery, preheating the vehicle or pre-air conditioning. Here, it is advantageous to use the external voltage as supply voltage and to compare it with the voltage of the high-voltage component, to which the power is supplied, in particular with the voltage of electric heater, air conditioner, charging device, and the charged high-voltage battery, so as to monitor a failure of the circuit.

According to an embodiment of the present disclosure, said comparison between the supply voltage and each component voltage is performed in respective control unit of the one or more high-voltage components respectively or performed in a central control device of the vehicle.

According to an embodiment of the present disclosure, a message for reporting failure information is output to the central control device of the vehicle or generated in the central control device when it is determined that a failure exists in the high-voltage circuit.

The present disclosure may relate to a distributed and a centralized failure monitoring. For example, the voltage comparison and failure determination may be performed at each high-voltage component, i.e. in its control unit, and a message for reporting failure information is output to the central control device of the vehicle. It is also possible that, all the voltage data are transmitted to the central control device, so that the voltage comparison and failure determination are performed and a message for reporting failure information is generated in the central control device.

According to an embodiment of the present disclosure, the central control device takes one or more of the following measures based on the message for reporting failure information:
shutting down the high-voltage power supply;
reporting the failure to vehicle users, especially outputting a check control message and/or a diagnostic trouble code;
reducing an overall operating power of the vehicle and/or the operating power of the high-voltage component(s) in association with the failure;
turning off the high-voltage component(s) in association with the failure;
disconnecting the cable connection to the high-voltage component(s) in association with the failure.

Through the above-mentioned measures, the safe operation of the vehicle is guaranteed, and the vehicle user or other vehicle components are prevented from being injured or damaged by high-voltage electricity. Besides, different measures also can be adopted according to the location of the failure. For example, only limiting, shutting down or turning off the operation of the high-voltage component(s) in association with the failure. Here, since the vehicle user usually cannot understand or only ignore vehicle fault reports, it is especially advantageous to reduce an overall operating power of the vehicle and/or the operating power of the high-voltage component(s) in association with the failure, because the vehicle user usually pays more attention to the decreased performance of a vehicle or its component.

The second aspect of the present disclosure relates to a computer readable storage medium having executable instructions, which, when executed, prompt a computer to perform the method according to the present disclosure.

The third aspect of the present disclosure relates to an equipment for monitoring a failure in a high-voltage circuit of a vehicle, the equipment including:
a supply voltage sensor for measuring a supply voltage of a high-voltage power supply device;
one or more component voltage sensors, which are respectively configured to measure a component voltage on each of one or more high-voltage components powered by the high-voltage power supply device;
voltage comparison device(s), which is configured to compare the supply voltage with the corresponding component voltage;
failure determination device(s), which is configured to determine that a failure exists in the high-voltage circuit when the voltage difference between the supply voltage and any one of the component voltage(s) exceeds a predetermined threshold.

According to an embodiment of the present disclosure, the voltage comparison device(s) and/or the failure determination device(s) are respectively provided in the respective control unit of the one or more high-voltage component(s), or the voltage comparison device(s) and/or the failure determination device(s) are centrally provided in a central control device of the vehicle. As mentioned above, the present disclosure may relate to a distributed and centralized failure monitoring. Here, the voltage comparison device may be arranged in the control unit of each high-voltage component, so that the control unit of each high-voltage component acquires the supply voltage of the high-voltage power supply device and the voltage comparison is performed by the voltage comparison device arranged on the high-voltage component. It is also possible that, the voltage measurement is merely performed at the high-voltage component, the measured voltage is transmitted to the central control device of the vehicle, so that the voltage comparison and the failure determination are performed in the central control device of the vehicle. Meanwhile, the failure determination device(s) may also be respectively provided in the respective control unit of the one or more high-voltage component(s) or centrally provided in a central control device of the vehicle. Here, in order to reduce the calculation amount of the central control device, it is preferable to arrange the voltage comparison device and the failure determination device respectively in the respective control unit of the one or more high-voltage component(s), so that each control unit only provides the central controller with the message for reporting the failure and if necessary, the message of whether or not it is operating normally.

According to an embodiment of the present disclosure, a fault type and a fault location are judged according to the voltage difference between the supply voltage and the respective component voltage. The technical advantage of the present disclosure with respect to the high-voltage interlock loop lies further in that, the present disclosure can effectively determine the failure location, namely the location where the voltage difference exceeds the predetermined threshold. For example, if it detects that the voltage difference between the component voltage of the electric heater and the supply voltage exceeds a predetermined threshold, it can be determined a failure exists at the electric heater, and said failure may involve the loose plug connection of the high-voltage cable at the electric heater or the short-circuit of the electric heater itself. For example, if it detects that the voltage differences between the component voltage of all the high-voltage components and the supply voltage exceed a predetermined threshold, the failure may involve the loose plug connection of the high-voltage cable at the high-voltage power supply device or the interruption of the high-voltage cable.

Particularly advantageously, different thresholds are respectively predetermined for the one or more high-voltage components based on the operating principle, the state change, the power demand of the high-voltage component as well as the voltage sensor accuracy. For example, since the drive means of a vehicle generally relies on DC/AC inverter to operate, a greater voltage fluctuation occurs on the drive device than other high-voltage components, so it is advantageous to predetermine a higher threshold value for the drive device. Besides, due to different control demands, voltage sensors of different accuracies may be provided on the high-voltage components. For instance, the high-voltage power supply device and the drive means are provided with more high-accuracy voltage sensors, while the electric heater or air conditioner is only provided with low-accuracy voltage sensor to save cost. Hence, it is expedient to predetermine different thresholds for high-voltage components.

The fourth aspect of the present disclosure relates to a high-voltage circuit system for a vehicle, said high-voltage circuit system comprising:
a high-voltage power supply device;
one or more high-voltage components;
the equipment for monitoring a failure in a high-voltage circuit of a vehicle according to the present disclosure.

According to an embodiment of the present disclosure, the high-voltage component includes but is not limited to one or more of the following: an electric heater, an air-conditioning device, a charging device and a drive device. Here, for the electric vehicle, it may relate to a single-motor centralized drive or multi-motor distributed drive. The drive device may include a front-wheel drive device and a rear-wheel drive device.

According to an embodiment of the present disclosure, the high-voltage circuit system further comprises a central control device of the vehicle, which takes one or more of the following measures based on a message for reporting failure from the equipment:
shutting down the high-voltage power supply;
reporting the failure to vehicle users, especially outputting a check control message and/or a diagnostic trouble code;
reducing an overall operating power of the vehicle and/or the operating power of the high-voltage component(s) in association with the failure;
turning off the high-voltage component(s) in association with the failure;
disconnecting the cable connection to the high-voltage component(s) in association with the failure.

The fifth aspect of the present disclosure relates to a vehicle including the high-voltage circuit system for a vehicle according to the present disclosure.

### BRIEF DESCRIPTION OF THE DRAWINGS

FIG. 1 shows a flowchart of an embodiment of a method for monitoring a failure in a high-voltage circuit of a vehicle according to the present disclosure.

FIG. 2 shows a flowchart of the other embodiment of a method for monitoring a failure in a high-voltage circuit of a vehicle according to the present disclosure.

FIG. 3 shows a block diagram of an embodiment of an equipment for monitoring a failure in a high-voltage circuit of a vehicle according to the present disclosure; and

FIG. 4 shows a schematic diagram of an embodiment of the high-voltage circuit system for a vehicle according to the present disclosure.

### DETAILED DESCRIPTION

To make the aforementioned objects, features and advantages of the present disclosure clearer and easier to understand, detailed explanations are made hereinafter for particular embodiments of the present disclosure by combining the drawings.

Details are explained below to facilitate a full comprehension of the present disclosure. However, the present disclosure can be implemented in manners other than what is explained here, and those skilled in the art can make a similar improvement without going against connotation of the present disclosure. Therefore, the present disclosure is not limited by the particular embodiments as disclosed below.

The expression “and/or” is used herein to include at least one of the components listed before and after the expression. Moreover, the expression “connection” is used herein to include a direct connection with another component, or an indirect connection through another component, such as cable. The singular form in the present disclosure also include the plural form unless specifically mentioned in the wording. Besides, the use of “comprising”, “including” or “having” the components, steps, operations, and elements means that there are or adding at least one other component, step, operation, and element.

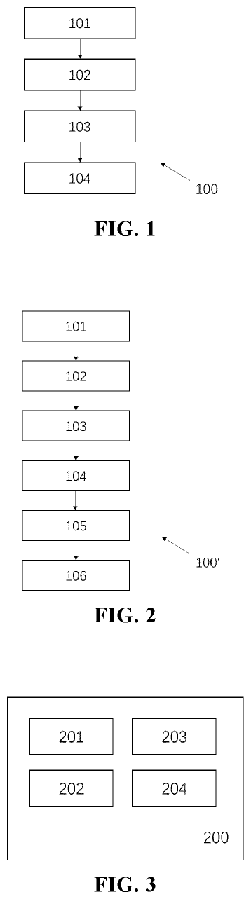

FIG. 1 shows a flowchart of an embodiment of a method for monitoring a failure in a high-voltage circuit of a vehicle according to the present disclosure. A method 100 for monitoring a failure in a high-voltage circuit of a vehicle, comprising:
Step 101: obtaining a supply voltage of a high-voltage power supply device;
Step 102: obtaining component voltage(s) on one or more high-voltage components powered by the high-voltage power supply device;
Step 103: comparing the supply voltage with each component voltage;
Step 104: determining that a failure exists in the high-voltage circuit when the voltage difference between the supply voltage and any one of the component voltage(s) exceeds a predetermined threshold.

Here, the failure may include but is not limited to: loosening of the plug connection of the high voltage cable at the high voltage power supply device, loosening of the plug connection of the high voltage cable at the high voltage component(s), interruption of the high voltage cable, short circuit of the high voltage component and open circuit of the high voltage component.

The supply voltage is: a battery voltage of a high-voltage battery in the high-voltage power supply device; or an intermediate circuit voltage of an intermediate circuit in the high-voltage power supply device; or an external voltage supplied to the vehicle by a power supply external to the vehicle.

FIG. 2 shows a flowchart of the other embodiment of a method for monitoring a failure in a high-voltage circuit of a vehicle according to the present disclosure. With respect to the method as shown in FIG. 1, the method 100′ for monitoring a failure in a high-voltage circuit of a vehicle further comprises the following steps:
Step 105: outputting a message for reporting failure information to the central control device of the vehicle or generating a message for reporting failure information in the central control device when it is determined that a failure exists in the high-voltage circuit;
Step 106: taking one or more of the following measures based on the message for reporting failure information:
   shutting down the high-voltage power supply;
   reporting the failure to vehicle users, especially outputting a check control message and/or a diagnostic trouble code;
   reducing an overall operating power of the vehicle and/or the operating power of the high-voltage component(s) in association with the failure;
   turning off the high-voltage component(s) in association with the failure;
   disconnecting the cable connection to the high-voltage component(s) in association with the failure.

FIG. 3 shows a block diagram of an embodiment of an equipment for monitoring a failure in a high-voltage circuit of a vehicle according to the present disclosure. An equipment 200 for monitoring a failure in a high-voltage circuit of a vehicle, comprising:
a supply voltage sensor 201 for measuring a supply voltage of a high-voltage power supply device;
one or more component voltage sensors 202, which are respectively configured to measure a component voltage on each of one or more high-voltage components powered by the high-voltage power supply device;
voltage comparison device(s) 203, which is configured to compare the supply voltage with the component voltage;
failure determination device(s) 204, which is configured to determine that a failure exists in the high-voltage circuit when the voltage difference between the supply voltage and any one of the component voltage(s) exceeds a predetermined threshold.

Here, it is possible that the voltage comparison device(s) 203 and/or the failure determination device(s) 204 are respectively provided in the respective control unit of the one or more high-voltage component(s); and/or the voltage comparison device(s) 203 and/or the failure determination device(s) 204 are centrally provided in a central control device of the vehicle.

Particularly advantageously, a fault type and a fault location may be judged according to the voltage difference between the supply voltage and the respective component voltage; and/or different thresholds are respectively predetermined for the one or more high-voltage components based on the operating principle, the state change, the power demand of the high-voltage component as well as the voltage sensor accuracy.

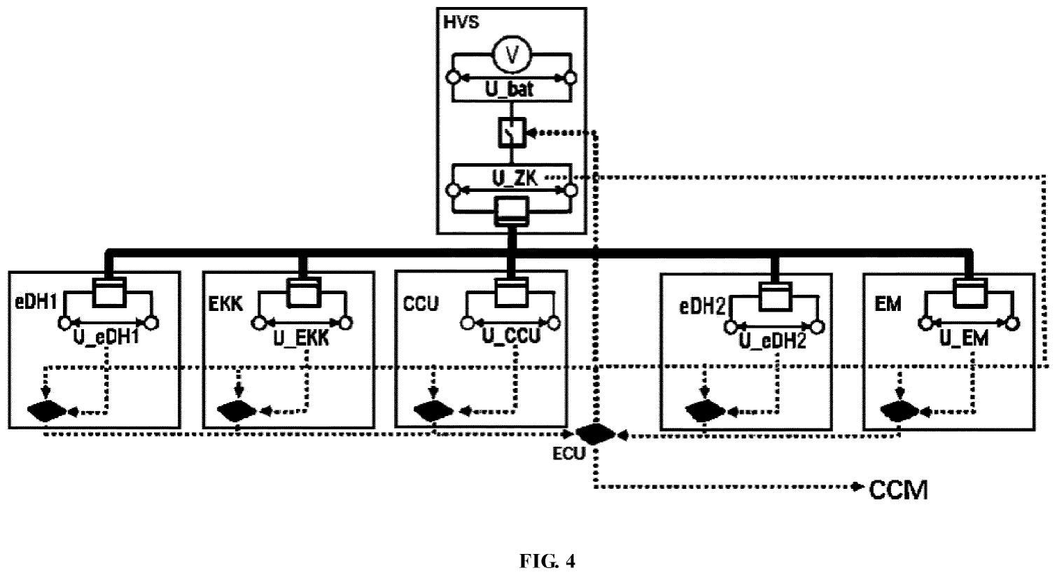

FIG. 4 shows a schematic diagram of the high-voltage circuit system for a vehicle according to the present disclosure. Here, a possible construction of the high-voltage circuit system is described in a schematic diagram. Said high-voltage circuit system comprising: a high-voltage power supply device HVS, a plurality of high-voltage components, the equipment for monitoring a failure in a high-voltage circuit of a vehicle according to the present disclosure, and a central control unit ECU in the vehicle.

Here, the high-voltage power supply device HVS includes high-voltage battery V and intermediate circuit. The high-voltage supply device HVS is provided with a supply voltage sensor for measuring a supply voltage of a high-voltage power supply device. A high-voltage battery voltage U_bat can be measured on the high-voltage battery, and an intermediate circuit voltage U_ZK can be measured on the intermediate circuit. The high-voltage battery V and the intermediate circuit are connected through a circuit breaker. When it is determined a failure exists in the high-voltage circuit, the high-voltage power supply can be advantageously cut off by the circuit breaker.

The plurality of high-voltage components include a first electric heater eDH1, a second electric heater eDH2, an air-conditioning device EKK, a drive device EM and a charging device CCU. These high-voltage components are connected to the high-voltage power supply device HVS via the high-voltage cable which is marked by solid line. FIG. 4 shows schematically that, each high-voltage component is provided with a control unit (not separately marked, for the clarity purpose) and a component voltage sensor for measuring the component voltage on the high-voltage components. As shown in the figure, each of the component voltage sensors respectively measures the component voltages U_eDH1, U_eDH2, U_EKK, U_EM and U_CCU on the aforesaid high-voltage components.

FIG. 4 schematically shows a distributed fault monitoring. That is, said comparison between the supply voltage and each component voltage is performed in respective control unit of the one or more high-voltage components respectively, or in other word, the voltage comparison device(s) 203 and/or the failure determination device(s) 204 of the equipment 200 for monitoring a failure in the high-voltage circuit of a vehicle are respectively provided in the respective control unit of the one or more high-voltage component(s). Here, the transmission of data and signal among the parts is represented by dotted line. Here, data and signal can be transmitted through the bus connected to each vehicle components, in particular CAN bus, but other media, such as wireless communication or separate signal line also can be considered.

The failure monitoring for the high-voltage circuit of a vehicle according to the present disclosure is performed as below. The supply voltage of the high-voltage supply device is measured by the supply voltage sensor for measuring a supply voltage of a high-voltage power supply device HVS. The intermediate circuit voltage U_ZK of the intermediate circuit in the high-voltage supply device is used here as supply voltage. The supply voltage is transmitted to the control unit of each high-voltage component. The component voltage of the high-voltage components is measured respectively by each component voltage sensor, and said component voltage is also transmitted to the control unit of the respective high-voltage component. In the voltage comparison device of the control unit, the supply voltage (here it is the intermediate circuit voltage U_ZK) is compared with the corresponding component voltage, and the failure determination device in the control unit determines that a failure exists in the high-voltage circuit when the voltage difference between the supply voltage and any one of the component voltage(s) exceeds a predetermined threshold. The corresponding control unit outputs a message for reporting failure information to the central control unit ECU of the vehicle when it is determined that a failure exists in the high-voltage circuit. The ECU can exemplarily adopt the measure as shown in FIG. 4 based on the message for reporting the failure: shutting down the high-voltage power supply by means of the circuit breaker in the high-voltage power supply device HVS and reporting the failure to vehicle users, i.e. outputting a check control message CCM.

Alternatively, the voltage comparison also can be performed only in the individual control units and the comparison result is transmitted to the central control unit ECU. The failure determination device provided only in the central control device is used to determine whether a failure exists in the high-voltage circuit.

Although FIG. 4 only exemplarily shows the distributed fault monitoring, yet it also can be implemented based on the aforesaid description in the specification, the intermediate circuit voltage U_ZK or the high-voltage battery voltage U_bat is transmitted to the central control unit ECU and the voltage comparison device and the failure determination device in the central control unit ECU are used for respectively performing the voltage comparison and the fault determination.

The present disclosure may further be a computer program product. The computer program product may include a computer-readable storage medium which enables the processor to execute the computer-readable program instructions of the aspects of the present disclosure.

The computer-readable storage medium may be a tangible device that can retain and store instructions for use by the instruction execution device. The computer readable storage medium may be, for example, but is not limited to, an electronic storage device, a magnetic storage device, an optical storage device, an electromagnetic storage device, a semiconductor storage device, or any suitable combination of the foregoing.

The computer-readable program instructions may be executed completely in the calculation unit of a vehicle, such as central control device. In some embodiments, an electronic circuit system including such as a programmable logic circuit system, a field programmable gate array (FPGA), or a programmable logic array (PLA), can execute the computer-readable program instructions by using the status information of the computer readable program instruction of the personalized electronic circuit system, in order to perform various aspects of the present disclosure.

This document describes various aspects of the present disclosure with reference to the flowcharts and/or block diagrams of the method, the system, and the computer program product in the embodiments according to the present disclosure. It should be understood that each block in the flowcharts and/or block diagrams and combinations of blocks in the flowcharts and/or block diagrams can be implemented by computer-readable program instructions.

The present disclosure is not limited to the embodiments shown, but includes or extends to all technical equivalents falling within the effective range of the appended claims. The positional descriptions selected in the description such as “top”, “bottom”, “left”, “right”, etc., refer to the direct description and the illustrated figures and can be transferred to new positions in accordance with the meaning when the position changes.

The features disclosed in this application document can be not only individually but also in any combination, which is important for the implementation of the embodiments in terms of different design solutions and can be realized.

Although some aspects are described in association with the device, it should be understood that these aspects are also explanations of corresponding methods, so that a device of a module or a device of a system can also be understood as a corresponding method step or a feature of a method step. Similarly, an aspect described in association with or as a method step is also an explanation of the corresponding module or details or features of the corresponding device.

Therefore, the computer-readable storage medium may be machine-readable or computer-readable. Therefore, in some embodiments, the computer-readable storage medium includes a data carrier. The data carrier has executable instructions, and the executable instructions can interact with a programmable computer system or programmable hardware components in such a way that one of the methods as described herein is implemented. Therefore, an embodiment is a data carrier, a data storage medium or a computer-readable storage medium. In the data carrier, a program for implementing one of the methods as described herein is recorded.

Although the present disclosure has been described in terms of preferred embodiments, it is not intended to limit the present disclosure thereto. Those skilled in the art can make variations and modifications to the present disclosure by utilizing the above-described methods and technical contents without departing from the spirit and scope of the present disclosure. Accordingly, any contents that do not depart from the technical solution of the present disclosure, and all such simple modifications, equivalents and alterations made to the aforesaid embodiments according to the technical spirit of the present disclosure, are considered as being within the protection scope of the technical solution of the present disclosure.

1-15. (canceled)

16. A method for monitoring a failure in a high-voltage circuit of a vehicle, the method comprising:
obtaining a supply voltage of a high-voltage power supply device;
obtaining at least one component voltage on one or more high-voltage components powered by the high-voltage power supply device;
comparing the supply voltage with each of the at least one component voltage; and
determining that a failure exists in the high-voltage circuit when a voltage difference between the supply voltage and any of the at least one component voltage exceeds a predetermined threshold.

17. The method according to claim 16, wherein:
the failure includes at least one of:
loosening of a plug connection of a high-voltage cable at the high-voltage power supply device;
loosening of a plug connection of the high-voltage cable at the one or more high-voltage components;
interruption or damage of the high-voltage cable;
short circuit of the one or more high-voltage components; and/or
open circuit of the one or more high-voltage components.

18. The method according to claim 16, wherein:
the supply voltage is one of:
a battery voltage of a high-voltage battery in the high-voltage power supply device;
an intermediate circuit voltage of an intermediate circuit in the high-voltage power supply device; or
an external voltage supplied to the vehicle by a power supply external to the vehicle.

19. The method according to claim 16,
wherein comparing the supply voltage with each of the at least one component voltage is performed in a respective control unit of the one or more high-voltage components, respectively, or performed in a central control device of the vehicle.

20. The method according to claim 19, comprising:
outputting a message for reporting failure information to the central control device of the vehicle, or generating the message for reporting failure information in the central control device, in response to determining that a failure exists in the high-voltage circuit.

21. The method according to claim 20, comprising:
the central control device taking one or more of the following measures based on the message for reporting failure information:
shutting down the high-voltage power supply;
reporting the failure to vehicle users comprising outputting a check control message and/or a diagnostic trouble code;
reducing an overall operating power of the vehicle and/or the operating power of the one or more high-voltage components in association with the failure;
turning off the one or more high-voltage components in association with the failure; and/or
disconnecting a cable connection to the one or more high-voltage components in association with the failure.

22. A computer-readable storage medium comprising executable instructions that, when executed by a computing device, cause the computing device to perform a method comprising:
obtaining a supply voltage of a high-voltage power supply device;
obtaining at least one component voltage on one or more high-voltage components powered by the high-voltage power supply device;
comparing the supply voltage with each of the at least one component voltage; and
determining that a failure exists in the high-voltage circuit when a voltage difference between the supply voltage and any of the at least one component voltage exceeds a predetermined threshold.

23. Equipment for monitoring a failure in a high-voltage circuit of a vehicle, the equipment comprising:
a supply voltage sensor for measuring a supply voltage of a high-voltage power supply device;
one or more component voltage sensors, which are respectively configured to measure at least one component voltage on each of one or more high-voltage components powered by the high-voltage power supply device;
at least one voltage comparison device, which is configured to compare the supply voltage with the at least one component voltage; and
at least one failure determination device, which is configured to determine that a failure exists in the high-voltage circuit when a voltage difference between the supply voltage and any one of the at least one component voltage exceeds a predetermined threshold.

24. The equipment according to claim 23, wherein:
the failure includes at least one of:
loosening of a plug connection of a high-voltage cable at the high-voltage power supply device;
loosening of a plug connection of the high-voltage cable at the one or more high-voltage components;
interruption or damage of the high-voltage cable;
short circuit of the one or more high-voltage components; and/or
open circuit of the one or more high-voltage components

25. The equipment according to claim 23, wherein:
the power supply voltage is one of:
a battery voltage of a high-voltage battery in the high-voltage power supply device;
an intermediate circuit voltage of an intermediate circuit in the high-voltage power supply device; or
an external voltage supplied to the vehicle by a power supply external to the vehicle.

26. The equipment according to claim 23, wherein:
the at least one voltage comparison device and/or the at least one failure determination device are respectively provided in a respective control unit of the one or more high-voltage components; and/or
the at least one voltage comparison device and/or the at least one failure determination device are centrally provided in a central control device of the vehicle.

27. The equipment according to claim 26, wherein
a message for reporting the failure is output to the central control device of the vehicle or generated in the central control device by the equipment in response to determining that a failure exists in the high-voltage circuit.

28. The equipment according to claim 23, wherein
a fault type and/or a fault location is judged according to the voltage difference between the supply voltage and a respective component voltage.

29. The equipment according to claim 23, wherein
different thresholds are respectively predetermined for the one or more high-voltage components based on an operating principle, a state change, a power demand of the high-voltage component, and/or the voltage sensor accuracy.

30. A high-voltage circuit system for a vehicle, the high-voltage circuit system comprising:
the equipment for monitoring a failure in the high-voltage circuit of the vehicle according to claim 23;
the high-voltage power supply device; and
the one or more high-voltage components.

31. The high-voltage circuit system according to claim 30, wherein the one or more high-voltage components includes one or more of an electric heater, an air-conditioning device, a drive device, and/or a charging device.

32. The high-voltage circuit system according to claim 30, comprising:
a central control device of the vehicle, which is configured to take one or more of the following measures based on a message for reporting failure from the equipment:
shut down the high-voltage power supply;
report the failure to a vehicle user by outputting a check control message and/or a diagnostic trouble code;
reduce an overall operating power of the vehicle and/or an operating power of the one or more high-voltage components in association with the failure;
turn off the one or more high-voltage components in association with the failure; and/or
disconnecting a cable connection to the one or more high-voltage components in association with the failure.

33. A vehicle comprising:
the high-voltage circuit system according to claim 30.
